(19) United States
(12) Patent Application Publication
(10) Pub. No.: US 2025/0372550 A1
(43) Pub. Date: Dec. 4, 2025

(54) SEMICONDUCTOR PACKAGE AND MANUFACTURING METHOD THEREOF

(71) Applicant: SAMSUNG ELECTRONICS CO., LTD., SUWON-SI (KR)

(72) Inventors: Pyunghwa HAN, Suwon-si (KR); Dongwon KANG, Suwon-si (KR); Bong-Soo KIM, Suwon-si (KR); Chobi KIM, Suwon-si (KR)

(21) Appl. No.: 18/963,607

(22) Filed: Nov. 28, 2024

(30) Foreign Application Priority Data
May 29, 2024 (KR) 10-2024-0070201

(51) Int. Cl. H01L 23/00; H01L 21/48; H01L 23/498; H01L 23/64; H01L 25/16

(52) U.S. Cl. CPC H01L 24/04; H01L 21/4857; H01L 23/49822; H01L 23/49838; H01L 23/642; H01L 24/03; H01L 24/05; H01L 24/06; H01L 24/16; H01L 25/16; H01L 24/32; H01L 2224/036; H01L 2224/0401; H01L 2224/05017; H01L 2224/05019; H01L 2224/0554; H01L 2224/05553; H01L 2224/05554; H01L 2224/05555; H01L 2224/05557; H01L 2224/05559; H01L 2224/06051; H01L 2224/06131; H01L 2224/16227; H01L 2224/32225; H01L 2224/73; H01L 2224/73204; H01L 2924/19041

(57) ABSTRACT

A semiconductor package includes: a package substrate including first and second sides that are opposite to each other, and including an insulating member and a plurality of redistribution layers; a semiconductor chip disposed on the first side and including a plurality of contact pads that are connected to a first redistribution layer of the plurality of redistribution layers; a protective layer disposed on the second side and exposing a portion of a second redistribution layer of the plurality of redistribution layers; a plurality of under bump metallurgy (UBM) pads disposed on the second side and connected to the exposed portion of the second redistribution layer; a dummy pattern formed on the protective layer; an insulating pattern covering the dummy pattern; and a passive element disposed on the insulating pattern and a first set of UBM pads of the plurality of UBM pads.

### CROSS-REFERENCE TO RELATED APPLICATION

This application claims priority under 35 U.S.C. § 119 to Korean Patent Application No. 10-2024-0070201, filed in the Korean Intellectual Property Office on May 29, 2024, the disclosure of which is incorporated by reference herein in its entirety.

### TECHNICAL FIELD

The present inventive concept relates to a semiconductor package and a manufacturing method thereof.

### DISCUSSION OF THE RELATED ART

In the case of a semiconductor package including a high-performance semiconductor chip, a system malfunction and performance degradation may occur due to voltage noise that may be generated in the high frequency band.

Therefore, packaging technology that can remove voltage noise and increase the power integrity (PI) of the semiconductor packages is desirable. For this purpose and as an example, passive elements may be mounted to the rear side of the semiconductor package.

However, when mounting the passive elements on the semiconductor package, cracks may occur in the passive elements due to external shocks, temperature changes, etc.

### SUMMARY

According to embodiments of the present inventive concept, a semiconductor package includes: a package substrate including first and second sides that are opposite to each other, and including an insulating member and a plurality of redistribution layers respectively disposed at a plurality of different levels of the insulating member and connected to each other; at least one semiconductor chip disposed on the first side and including a plurality of contact pads that are connected to a first redistribution layer of the plurality of redistribution layers that is adjacent to the first side; a protective layer disposed on the second side and exposing a portion of a second redistribution layer of the plurality of redistribution layers that is adjacent to the second side; a plurality of under bump metallurgy (UBM) pads disposed on the second side and connected to the exposed portion of the second redistribution layer; a dummy pattern formed on the protective layer and protruding from the protective layer; an insulating pattern covering at least a portion of the dummy pattern; and a passive element disposed on the insulating pattern and a first set of UBM pads of the plurality of UBM pads, and connected to at least some of the first set of UBM pads.

According to embodiments of the present inventive concept, a semiconductor package includes: a package substrate including first and second sides that are opposite to each other, and including an insulating member and a plurality of redistribution layers respectively disposed at a plurality of different levels of the insulating member and connected to each other; at least one semiconductor chip disposed on the first side and including a plurality of contact pads that are connected to a first redistribution layer of the plurality of redistribution layers that is adjacent to the first side; a protective layer disposed on the second side and exposing a portion of a second redistribution layer of the plurality of redistribution layers that is adjacent to the second side; a plurality of UBM pads disposed on the second side and connected to the exposed portion of the second redistribution layer; a dummy pattern formed on the protective layer; an insulating pattern disposed on the dummy pattern; and a passive element in contact with the insulating pattern, disposed on a first set of UBM pads of the plurality of UBM pads, and connected to at least some of the first set of UBM pads, wherein the dummy pattern includes: a first dummy pad disposed at a center of a unit lattice including four UBM pads of the first set of UBM pads; and a second dummy pad disposed between adjacent UBM pads of the first set of UBM, the first dummy pad and the second dummy pad are integrally formed with each other, and the dummy pattern and the plurality of UBM pads are formed to be spaced apart from each other on the second side.

According to embodiments of the present inventive concept, a manufacturing method of a semiconductor package includes: manufacturing a package substrate including first and second sides that are opposite to each other, and including an insulating member and a plurality of redistribution layers respectively disposed at a plurality of different levels of the insulating member and connected to each other; forming a protective layer on the second side and exposing a portion of a second redistribution layer of the plurality of redistribution layers that is adjacent to the second side; forming a plurality of UBM pads on the protective layer, wherein the UBM pads are disposed on the second side and adjacent to a dummy pattern, wherein the UBM pads are disposed on the exposed portion of the second redistribution layer; forming an insulating pattern to cover the dummy pattern; and placing a passive element on at least some UBM pads of the plurality of UBM pads and to be in contact with the insulating pattern.

### BRIEF DESCRIPTION OF THE DRAWINGS

FIG. 1 is a cross-sectional view illustrating a semiconductor package according to an embodiments of the present inventive concept;

FIG. 2A is a plan view illustrating the portion ‘A’ illustrated in FIG. 1;

FIG. 2B is a plan view illustrating a variation of the passive element illustrated in FIGS. 1 and 2A;

FIG. 3A is a diagram illustrating a region ‘B’ of FIG. 1;

FIGS. 3B and 3C are diagrams illustrating variations of the insulating pattern illustrated in FIGS. 1 and 3A;

FIGS. 4A and 4B are diagrams illustrating an example where the dummy pattern and the insulating pattern are formed in the mounting region of FIGS. 2A and 2B;

FIGS. 5A, 5B, 6A, 6B, 7A, 7B, and 7C are diagrams illustrating a shape of the dummy pattern according to embodiments of the present inventive concept;

FIGS. 8A, 8B, 8C, 8D, 8E, and 8F are cross-sectional views illustrating processes steps of a manufacturing method of the semiconductor package according to embodiments of the present inventive concept;

FIG. 9 is a cross-sectional view illustrating a semiconductor package according to embodiments of the present inventive concept; and

FIG. 10 is a block diagram illustrating a configuration of a semiconductor package according to embodiments of the present inventive concept.

### DETAILED DESCRIPTION OF THE EMBODIMENTS

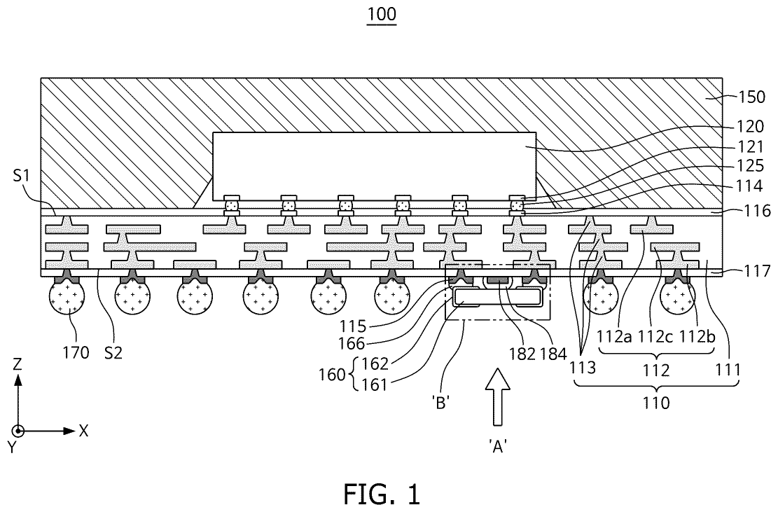

Hereinafter, embodiments of the present inventive concept will be described with reference to FIGS. 1 to 10. The same reference numerals may refer to the same components throughout the specification and drawings, and thus, their descriptions may be omitted or briefly described.

FIG. 1 is a cross-sectional view illustrating a semiconductor package 100 according to embodiments of the present inventive concept.

Referring to FIG. 1, the semiconductor package 100 may include a package substrate 110, a semiconductor chip 120, and a passive element 160. The semiconductor package 100 may further include an encapsulant 150 and a connection bump 170.

The package substrate 110 is a support substrate on which the semiconductor chip 120 is mounted, and may be a redistribution structure for redistributing a contact pad 121 of the semiconductor chip 120. For example, the package substrate 110 may be a printed circuit board (PCB).

The package substrate 110 may include an insulating member 111, a redistribution layer 112, and a redistribution via 113 disposed in the insulating member 111.

The insulating member 111 may include an insulating resin. The insulating resin may include a thermosetting resin such as an epoxy resin, a thermoplastic resin such as polyimide, or these resins impregnated with an inorganic filler or/and glass fiber (glass fiber, glass cloth, glass fabric), such as prepreg, ABF, FR-4, BT, or a photosensitive resin such as photo-imageable dielectric (PID).

The insulating member 111 may be formed by stacking any number of a plurality of insulating layers on each other in a vertical direction (e.g., in Z-axis direction). In FIG. 1, the insulating member 111 is illustrated without boundaries or interfaces between the plurality of insulating layers, but the present inventive concept is not limited thereto.

For example, the redistribution layer 112 may include a metal material including copper (Cu), aluminum (Al), silver (Ag), tin (Sn), gold (Au), nickel (Ni), lead (Pb), titanium (Ti), or an alloy thereof.

The redistribution layer 112 may include a plurality of redistribution layers 112a, 112b, and 112c, each of which is respectively disposed at a different level of the insulating member 111. For example, the redistribution layer 112 may include a first redistribution layer 112a, a second redistribution layer 112b, and a third redistribution layer 112c. The first redistribution layer 112a may be adjacent to a first side S1 of the package substrate 110, and the second redistribution layer 112b is adjacent to a second side S2 of the package substrate 110. The third redistribution layer 112c is positioned between the first redistribution layer 112a and the second redistribution layer 112b. Embodiments of the present inventive concept are not limited to the above, and the redistribution layer 112 may include more or fewer layers than what is illustrated in the drawings. The number of layers of the plurality of redistribution layers may be determined according to the thickness or the number of layers of the insulating member 111.

The redistribution via 113 may electrically connect the plurality of redistribution layers 112a, 112b, and 112c to each other. The redistribution via 113 may be electrically connected to the redistribution layer 112 and may include, for example, a signal via, a ground via, and a power via.

For example, the redistribution via 113 may include a metal material including copper (Cu), aluminum (Al), silver (Ag), tin (Sn), gold (Au), nickel (Ni), lead (Pb), titanium (Ti), or an alloy thereof. The redistribution via 113 may have a form of a filled via where a metal material fills the inside of the via hole, or of a conformal via in which a metal material is formed along an inner wall of a via hole. For example, the redistribution via 113 may be integrated with the redistribution layer 112, but the present inventive concept is not limited thereto.

The package substrate 110 may have the first side S1 and the second side S2 that is disposed opposite to the first side S1. The first side S1 and the second side S2 may be referred to as a front side and a back side of the package substrate 110, respectively. A first side protective layer 116, which covers the first side S1, and a second side protective layer 117, which covers the second side S2, may be disposed on the package substrate 110. The first side protective layer 116 and the second side protective layer 117 may protect the package substrate 110 from external physical and chemical damages. For example, the first side protective layer 116 and the second side protective layer 117 may include a solder resist material or a photo solder resist material.

A first side pad 114 may be disposed on the first side S1 of the package substrate 110. The first side pad 114 may be electrically connected to the redistribution layer 112 through the redistribution via 113.

The first side pad 114 may include the same material as that of the redistribution layer 112 and/or the redistribution via 113. For example, the first side pad 114 may include a metal material including copper (Cu), aluminum (Al), silver (Ag), tin (Sn), gold (Au), nickel (Ni), lead (Pb), titanium (Ti), or alloys of these materials. For example, the first side pad 114 may be disposed on the first side S1 of the package substrate 110 such that it protrudes from beyond the first side S1, but the present inventive concept is not limited thereto. For example, a lower surface of the first side pad 114 may be coplanar with or disposed above the first side S1.

The first side pad 114 may be used as a landing pad to which the semiconductor chip 120 is connected.

The semiconductor chip 120 may be connected to the first side pad 114 through the contact pad 121 and a metal bump. The contact pad 121 may be a pad of a bare chip (e.g., an aluminum pad) or a pad of a packaged chip (e.g., a copper pad). The metal bump may be in the form of a ball or a post. The semiconductor chip 120 may be electrically connected to the first side pad 114 through the contact pad 121 and a solder bump 125. In addition, the semiconductor chip 120 may be directly connected to the first side pad 114 or the redistribution via 113 without a separate bump, or may be mounted to the package substrate 110 by using a wire bonding method.

The semiconductor chip 120 may include, for example, silicon (Si), germanium (Ge), or gallium arsenide (GaAs), and various types of integrated circuits may be formed in the semiconductor chip 120. The integrated circuits may be a processor chip such as a central processor (e.g., CPU), a graphics processor (e.g., GPU), a field programmable gate array (FPGA), an application processor (AP), a digital signal processor, an encryption processor, a microprocessor, a microcontroller, but the present inventive concept is not limited thereto, and for example, the integrated circuit may be logic chips such as analog-to-digital converters, application-specific ICs (ASICs), or memory chips such as volatile memories (e.g., DRAMs), non-volatile memories (e.g., ROMs and flash memories), etc.

The encapsulant 150 may encapsulate at least a portion of the semiconductor chip 120 on the first side protective layer 116. The encapsulant 150 may be disposed on the semiconductor chip 120 and the first side protective layer 116. For example, the encapsulant 150 may include a thermosetting resin such as an epoxy resin, a thermoplastic resin such as polyimide, or prepreg, ABF, FR-4, BT, and epoxy molding compound (EMC) containing an inorganic filler and/or glass fiber. The encapsulant 150 may have a molded underfill (MUF) structure that is integrally formed with an underfill resin between the semiconductor chip 120 and the package substrate 110, but the present inventive concept is not limited thereto. Depending on the embodiment, the encapsulant 150 may also have a capillary underfill (CUF) structure in which an underfill resin under the semiconductor chip 120 is distinct.

A plurality of under bump metalization (UBM) pads 115 may be disposed on the second side S2 of the package substrate 110. The plurality of UBM pads 115 may be connected to a portion of the second redistribution layer 112b that is exposed from the second side protective layer 117, thereby being electrically connected to the redistribution layer 112. An opening may be formed in the second side protective layer 117 such that the portion of the second redistribution layer 112b is exposed on the bottom side of the second side protective layer 117.

The plurality of UBM pads 115 may include the same material as the redistribution layer 112. For example, the plurality of UBM pads 115 may include a metal material including at least one of copper (Cu), aluminum (Al), silver (Ag), tin (Sn), gold (Au), nickel (Ni), lead (Pb), titanium (Ti), or an alloy thereof.

The plurality of UBM pads 115 may be disposed such that at least a portion of each of the plurality of UBM pads 115 protrudes from the second side protective layer 117. However, the present inventive concept is not limited thereto, and for example, the lower side of the plurality of UBM pads 115 may be disposed at the same level as or higher than the lower side of the second side protective layer 117.

The plurality of UBM pads 115 may be used as landing pads to which the passive element 160 and/or the connection bump 170 are connected.

The passive element 160 may be mounted such that it is disposed on an insulating pattern 184 that covers at least a portion of a dummy pattern 182, and may be connected to at least some of the plurality of UBM pads 115. For example, the passive element 160 may be in contact with the insulating pattern 184. For example, the passive element 160 may include an element body 161 and a connection terminal 162 that electrically connects the passive element 160 to an outside element or device. The connection terminal 162 may be connected to at least some of the plurality of UBM pads 115 through solder paste 166 that is applied on the plurality of UBM pads 115. The connection terminal 162 may be disposed at a corner portion of the passive element 160. For example, the connection terminal 162 may extend along an upper surface, a side surface, and a lower surface of the element body 161.

The passive element 160 may include, for example, a capacitor, an inductor, beads, etc., although the present inventive concept is not limited thereto. The passive element 160 may be a chip-type silicon (Si) capacitor or a land side capacitor (LSC), which have a high electrical capacity.

The connection bump 170 may be electrically connected to the redistribution layer 112. The connection bump 170 may physically and/or electrically connect the semiconductor package 100 to an external device. The connection bump 170 may include a conductive material, and may be in the form of a ball, a pin, or a lead. For example, the connection bump 170 may be a solder ball. The connection bump 170 may have a height that is greater than a height at which the passive element 160 is mounted in a direction perpendicular to a lower surface of the second side protective layer 117 (e.g., in a −Z axis direction). For example, the connection bump 170 may have a thickness that is greater than that of the passive element 160.

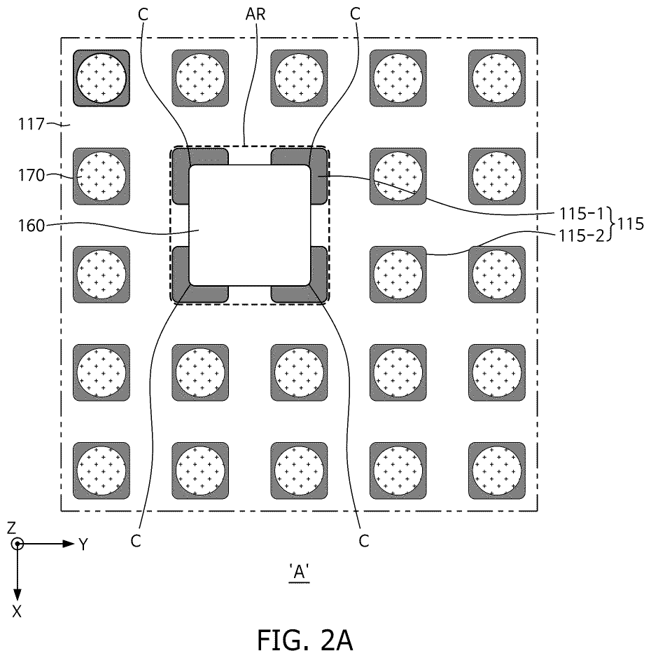

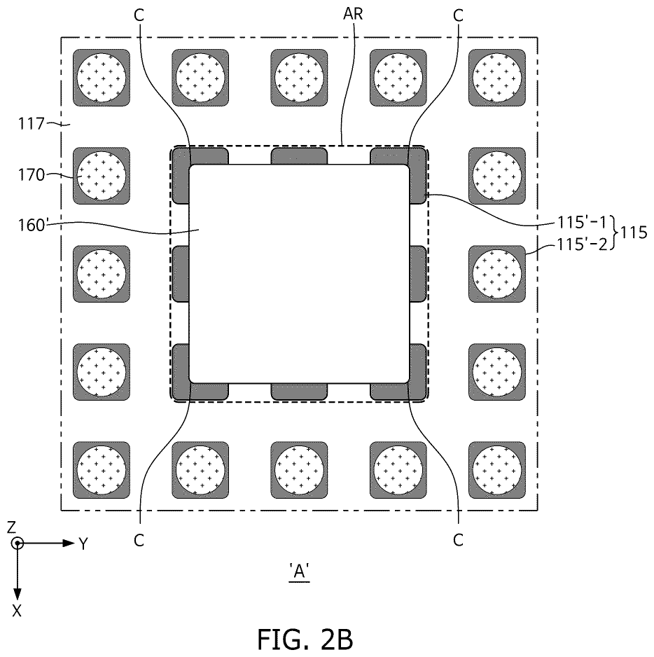

FIG. 2A is a plan view illustrating the portion ‘A’ illustrated in FIG. 1. Referring to FIGS. 1 and 2A, the plurality of UBM pads 115 may be arranged in a grid structure in which square unit lattices are repeated along a row direction (e.g., X direction) and a column direction (e.g., Y direction) on the second side S2 of the package substrate 110 on which the second side protective layer 117 is formed. The present inventive concept is not limited to the above, and for example, the plurality of UBM pads 115 may be arranged in a grid structure of repeating unit lattices, and the unit lattice may be in the form of parallelogram, rectangle, square, regular hexagon, or rhombus. Additionally, the plurality of UBM pads 115 may be arranged in a grid structure, with some UBM pads at positions corresponding to specific intersections within the grid structure potentially being omitted.

The passive element 160 may be disposed on a first set of UBM pads 115-1 of the plurality of UBM pads 115, and may be connected to the first set of UBM pads 115-1. For example, corners C of the passive elements 160 may each be disposed on the first set of UBM pads 115-1, and at least some of the first set of UBM pads 115-1 may be connected to the connection terminal of the passive element 160. For example, each of the corners C of the passive element 160 may be disposed at the center of each of the first set of UBM pads 115-1.

An area of one surface of the passive element 160 may be less than the area of a mounting region AR of the passive element 160, which includes the region where the first set of UBM pads 115-1 are disposed.

The connection bump 170 may be disposed on a second set of UBM pads 115-2 of the plurality of UBM pads 115, and the second set of UBM pads 115-2 are different from the first set of UBM pads 115-1. The passive element 160 might not be disposed on the second set of UBM pads 115-2 that are different from the first set of UBM pads 115-1.

FIG. 2B is a plan view illustrating a variation of the passive element 160 illustrated in FIGS. 1 and 2A. Unlike FIG. 2A, the passive element 160′ may be disposed on three or more UBM pads that are arranged in a first direction (e.g., X direction) and/or a second direction (e.g., Y direction).

The passive element 160′ may be disposed on a first set of UBM pads 115′-1 of the plurality of UBM pads 115, and may be connected to at least some of the first set of UBM pads 115′-1. For example, the passive element 160′ may be connected to a UBM pad, of the first set of UBM pads 115′-1, that overlaps with the corner C of the passive element 160′.

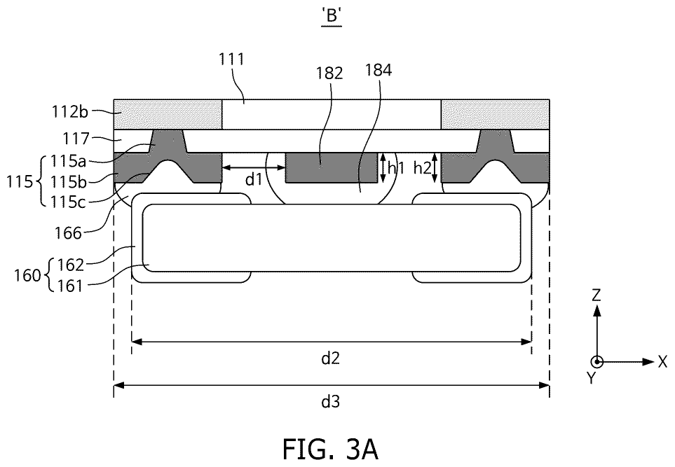

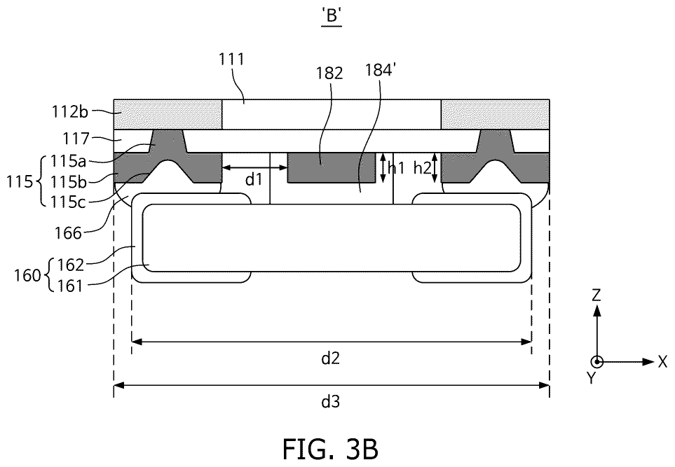

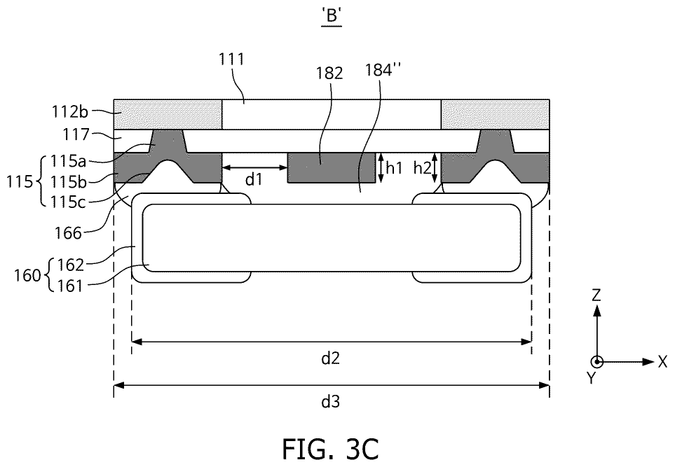

FIG. 3A is a diagram illustrating a region ‘B’ of FIG. 1. The UBM pad 115 may include a via portion 115a and a pad portion 115b. The via portion 115a may connect the UBM pad 115 to the second redistribution layer 112b, and the pad portion 115b may protrude beyond the second side protective layer 117 and may be connected to the passive element 160. For example, the pad portion 115b may be disposed on a lower surface of the second side protective layer 117. The pad portion 115b may be connected to the passive element 160 through the solder paste 166. A concave portion 115c may be formed in the pad portion 115b. In addition, the via portion 115a may be omitted and the pad portion 115b may be directly connected to the second redistribution layer 112b, or the concave portion 115c might not be formed in the pad portion 115b.

A portion of the passive element 160 may be supported by the dummy pattern 182 and the insulating pattern 184. For example, a region of the passive element 160 that is not supported by the UBM pad 115 may be supported by the dummy pattern 182 and the insulating pattern 184. As a result, cracks in the passive element 160 may be prevented and physical stability may be increased.

The dummy pattern 182 may be formed (or, disposed) on the second side protective layer 117 and may protrude from the second side protective layer 117. In addition, the dummy pattern 182 may be formed on the insulating member 111 and may extend beyond the second side protective layer 117.

Referring to FIGS. 1 and 3A, the dummy pattern 182 may be formed on the second side S2 and spaced apart from the plurality of UBM pads 115. For example, a distance d1 between the dummy pattern 182 and the UBM pad of the plurality of UBM pads 115, which is adjacent to the dummy pattern 182 in a direction (e.g., X direction) that is parallel to the second side S2, may be about 10 μm to about 15 μm. As a result, a short between the UBM pad 115 and the dummy pattern 182 may be prevented.

The insulating pattern 184 may cover at least a portion of the dummy pattern 182. For example, the insulating pattern 184 may cover sides and lower side of the dummy pattern 182. As a result, a short circuit between the UBM pad 115 or the connection terminal 162 and the dummy pattern 182 may be prevented. As illustrated in FIG. 3A, a side surface of the insulating pattern 184 may be formed to have a curved shape.

The insulating pattern 184 may include an insulating resin. The insulating resin may include a thermosetting resin such as an epoxy resin, a thermoplastic resin such as polyimide, or these resins impregnated with an inorganic filler or/and glass fiber (glass fiber, glass cloth, glass fabric), such as prepreg, ABF, FR-4, BT, or a photosensitive resin such as photo-imageable dielectric (PID).

A thickness h1 of the dummy pattern 182 may be the same as a thickness h2 of the pad portion 115b of the UBM pad 115 protruding from the second side protective layer 117, or may be greater than the thickness h2 of the pad portion 115b. For example, the protruding thickness of the pad portion 115b may be about 80% to about 100% of the thickness of the dummy pattern 182. As a result, sufficient support force may be provided for the passive element 160, and physical damage to the passive element 160 may be prevented.

A width d2 of the passive element 160 may be equal to or shorter than a distance d3 that is between ends of UBM pads 115 that are connected to the passive element 160. The distance d3 may be between ends of a pair of UBM pads 115 that are connected to the passive element 160.

FIG. 3A illustrates that the passive element 160 is disposed on two adjacent UBM pads 115 for convenience of explanation, but the present inventive concept is not limited thereto. For example, the passive element 160 may be disposed on three or more UBM pads 115 in the width d2 direction of the passive element 160, and the dummy pattern 182 and the insulating pattern 184 may be formed between each of the adjacent UBM pads 115 among the three or more UBM pads 115 on which the passive element 160 is arranged.

FIGS. 3B and 3C are diagrams illustrating variations of the insulating pattern 184 illustrated in FIGS. 1 and 3A. Referring to FIG. 3B, the insulating pattern 184′ as a whole may be formed in a rectangular shape. A side portion of the insulating pattern 184′ may be formed in a vertical direction extending from the second side protective layer 117. Referring to FIG. 3C, the insulating pattern 184′ may be formed to be in contact with the UBM pad 115 that is adjacent to the dummy pattern 182 that is covered by the insulating pattern 184′.

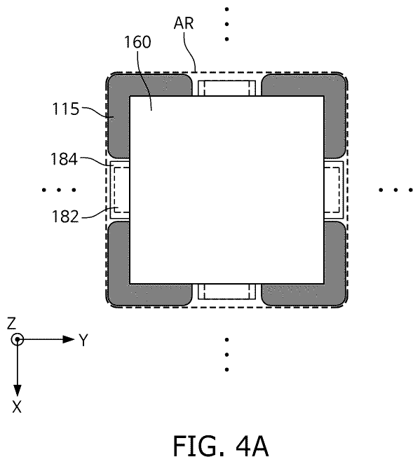

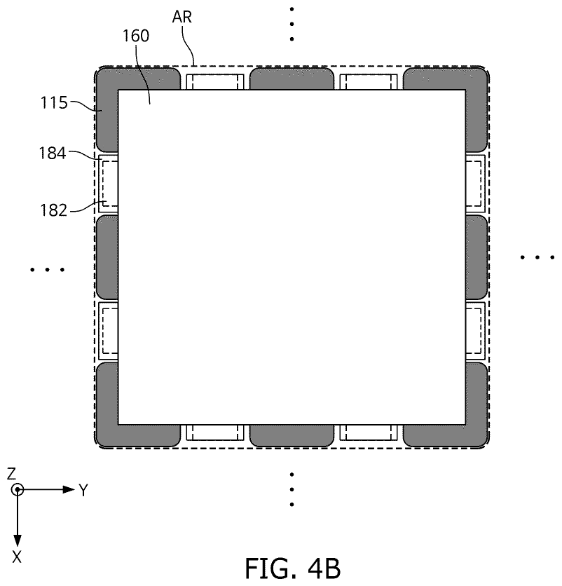

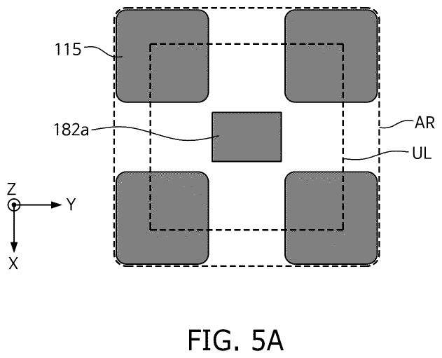

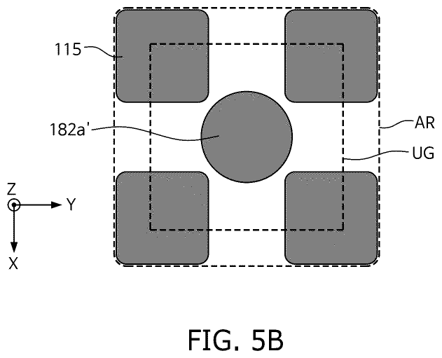

FIGS. 4A and 4B are diagrams illustrating an example where the dummy pattern 182 and the insulating pattern 184 are formed in the mounting region AR of FIGS. 2A and 2B. The dummy pattern 182 and the insulating pattern 184 may be formed to support at least a portion of the passive element 160 that is not supported by the UBM pad 115. The insulating pattern 184 may be formed to cover the dummy pattern 182, and various embodiments of the dummy pattern 182 will be described in detail below with reference to FIGS. 5A to 7C.

FIGS. 5A to 7C are diagrams illustrating a shape of the dummy pattern 182 according to embodiments of the present inventive concept. For convenience of description, FIGS. 5A to 7C illustrate that the mounting region AR for the passive device includes a region in which four UBM pads 115 are disposed, but the present inventive concept is not limited thereto. For example, if the mounting region (AR) includes a region in which five or more UBM pads 115 are disposed, it should be understood that dummy pads may be disposed in other locations in the mounting region (AR) according to the aspects of FIGS. 5A to 7C. For example, dummy pads may be disposed in the center that is between any four UBM pads 115 of the unit lattice in the mounting region (AR) and/or between any two adjacent UBM pads.

Referring to FIGS. 5A and 5B, first dummy pads 182a and 182a′ may be formed in (or, disposed at) the center of the unit lattice UL formed by the four UBM pads 115 in the mounting region AR. As illustrated in FIGS. 5A and 5B, the first dummy pads 182a and 182a′ may be formed to have a square or circular shape. In addition, dummy pads of various shapes may be formed in the center of the unit lattice UL.

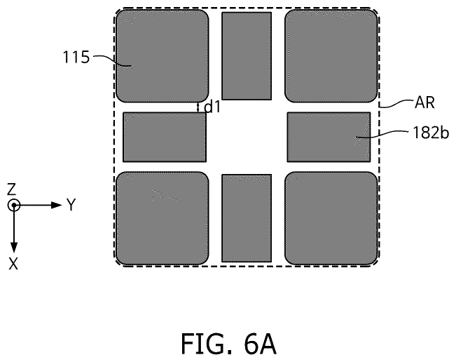

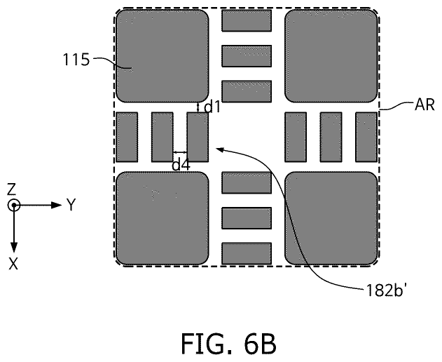

Referring to FIGS. 6A and 6B, second dummy pads 182b and 182b′ may be formed (or, disposed) between any two adjacent UBM pads 115 in the mounting region AR.

In FIG. 6B, the second dummy pad 182b′ may be formed to include any number (e.g., three) of pads that are separated from each other. A distance d4, which is between each of a plurality of pads that are separated from each other, may be equal to or greater than the distance d1, which is between the second dummy pads 182b and 182b′ and the UBM pad 115 adjacent thereto.

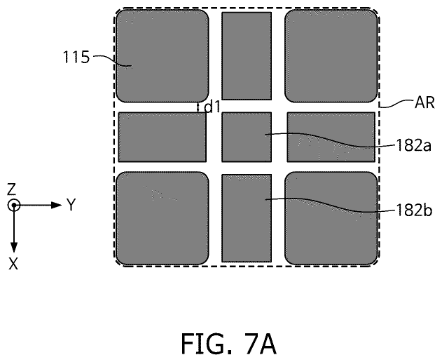

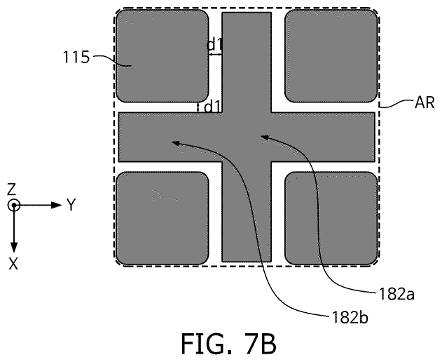

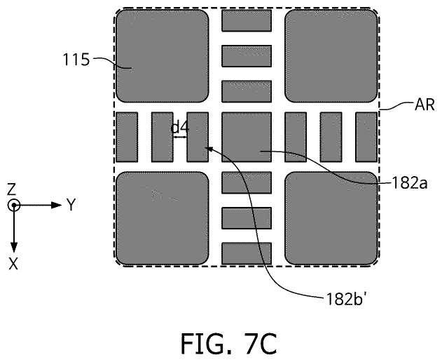

Referring to FIGS. 7A to 7C, the first dummy pad 182a described above with reference to FIGS. 5A and 5B, and the second dummy pads 182b and 182b′ described above with reference to FIGS. 6A and 6B may be formed in the mounting region AR.

In FIG. 7B, the first dummy pad 182a and the second dummy pad 182b may be integrally formed with each other to form a single body.

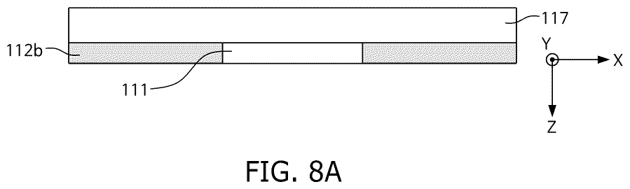

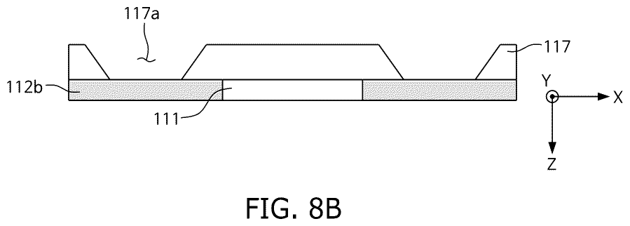

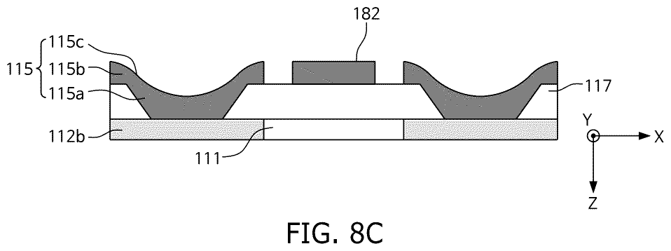

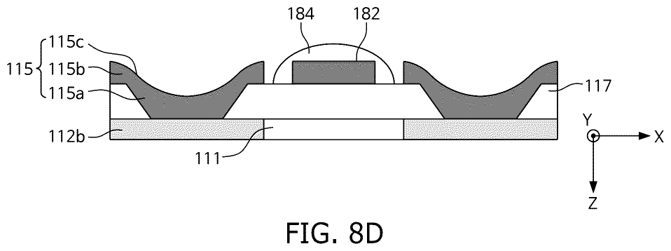

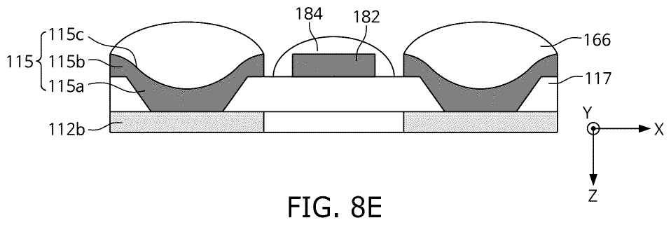

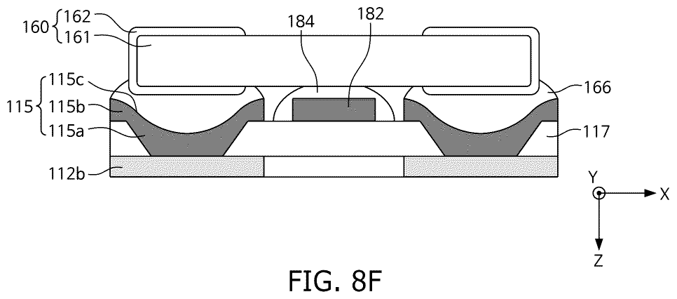

FIGS. 8A to 8F are cross-sectional views illustrating processes steps of a manufacturing method of the semiconductor package according to embodiments of the present inventive concept.

Referring to FIG. 8A, the package substrate (e.g., 110 in FIG. 1) including the second redistribution layer 112b and the insulating member 111 may be manufactured, and the second side protective layer 117 may be formed on the second redistribution layer 112b and the insulating member 111.

Referring to FIG. 8B, a via hole 117a may be formed in the second side protective layer 117 to expose a portion of the second redistribution layer 112b to the outside. The via hole 117a is illustrated as being formed in a trapezoidal shape, but the present inventive concept is not limited thereto. For example, the via hole 117a may be formed to have a rectangular shape.

Referring to FIG. 8C, the UBM pad 115 and the dummy pattern 182 may be formed on the second side protective layer 117. The UBM pad 115 may include the via portion 115a that is formed in the via hole 117a of FIG. 8B to connect the UBM pad 115 to the second redistribution layer 112b. The UBM pad 115 may also include the pad portion 115b that is associated with the via portion 115a. The pad portion 115b is connected to the via portion 115a.

The UBM pad 115 and the dummy pattern 182 may be formed by the same patterning. Accordingly, the UBM pad 115 and the dummy pattern 182 may be formed of the same material. As the UBM pad 115 is formed on the via hole 117a of FIG. 8A, the concave portion 115c may be formed in the pad portion 115b of the UBM pad 115.

Referring to FIG. 8D, the insulating pattern 184 may be formed to cover the dummy pattern 182.

Referring to FIG. 8E, the solder paste 166 may be applied on the UBM pad 115.

Referring to FIG. 8F, the passive element 160 that is connected to the UBM pad 115 may be disposed to be in contact with the insulating pattern 184. For example, the element body 161 of the passive element 160 may be in contact with the insulating pattern 184, and the connection terminal 162 of the passive element 160 may be in contact with the solder paste 166 so as to be electrically connected to the UBM pad 115.

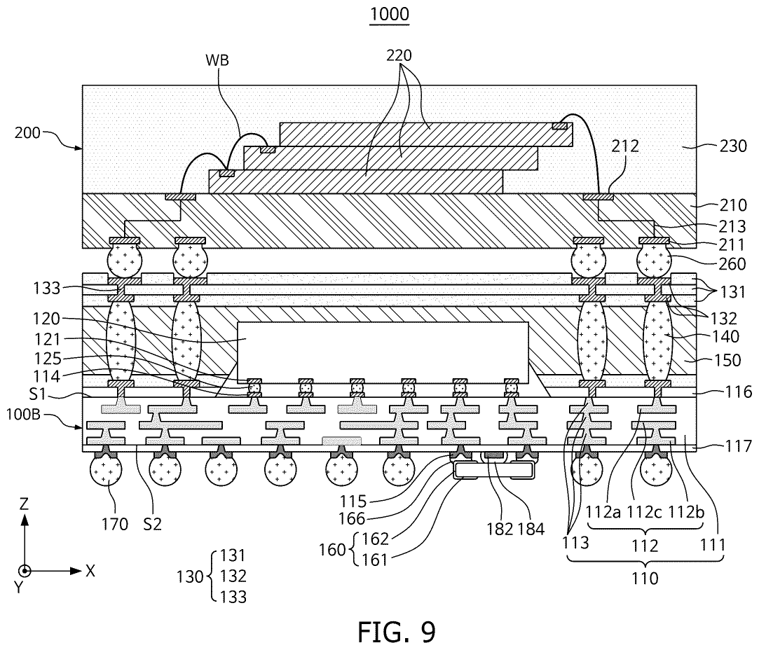

FIG. 9 is a cross-sectional view illustrating a semiconductor package 1000 according to embodiments of the present inventive concept. Referring to FIG. 9, the semiconductor package 1000 may include a first semiconductor package 100B and a second semiconductor package 200. It can be understood that the first semiconductor package 100B has the same or similar characteristics as the semiconductor package 100 described above with reference to FIGS. 1 to 8 except that the semiconductor package 100B further includes an interposer substrate 130 and a connection structure 140.

The interposer substrate 130 is a redistribution substrate that provides a redistribution layer on a top or back side of the first semiconductor package 100B, and may be located between the lower package and the upper package in a package-on-package structure. The interposer substrate 130 may be disposed on the semiconductor chip 120 and include an upper insulating layer 131, an upper distribution layer 132, and a distribution via 133. Since the upper insulating layer 131, the upper distribution layer 132, and the distribution via 133 have the same or similar characteristics as the insulating member 111, the redistribution layer 112, and the redistributing via 113 of the package substrate 110 described above, descriptions that are redundant or overlap with descriptions that have already been described above will be omitted. The upper insulating layer 131 may also be provided as a plurality of insulating layers. The uppermost one of the upper insulating layers 131 may include openings exposing at least a portion of the upper distribution layer 132.

The connection structure 140 may be disposed between the package substrate 110 and the interposer substrate 130 to electrically connect the package substrate 110 and the interposer substrate 130 to each other. The connection structure 140 may extend in the vertical direction (Z-axis direction) between the package substrate 110 and the interposer substrate 130, thereby providing a vertical connection path to electrically connect the redistribution layer 112 and the upper distribution layer 132 to each other. For example, the connection structure 140 may have a curved, spherical, or ball shape and include a low melting point metal such as tin (Sn), indium (In), bismuth (Bi), antimony (Sb), copper (Cu), silver (Ag), zinc (Zn), lead (Pb), or an alloy (e.g., Sn—Ag—Cu) thereof. A core ball made of a thermoplastic resin, a polymer material including the thermosetting resin, or a metal material distinguished from solder may be disposed inside the connection structure 140.

The second semiconductor package 200 may include a redistribution substrate 210, a second semiconductor chip 220, and a second encapsulant 230. The redistribution substrate 210 may include a lower pad 211 and an upper pad 212 on a lower side and an upper side of the redistribution substrate 210, respectively, which may be electrically connected to the outside. In addition, the redistribution substrate 210 may include a redistribution circuit 213 electrically connecting the lower pad 211 and the upper pad 212 to each other.

The second semiconductor chip 220 may be mounted to the redistribution substrate 210 by using a wire bonding or flip chip bonding method. For example, a plurality of second semiconductor chips 220 may be stacked on the redistribution substrate 210 in a vertical direction and may be electrically connected to the upper pad 212 of the redistribution substrate 210 by a bonding wire WB. For example, the second semiconductor chip 220 may include a memory chip, and the first semiconductor chip 120 of the first semiconductor package 100B may include an AP chip.

The second encapsulant 230 may include the same or similar material as the encapsulant 150 of the first semiconductor package 100B. The second semiconductor package 200 may be physically and electrically connected to the first semiconductor package 100B through a metal bump 260. The metal bump 260 may be electrically connected to the redistribution circuit 213, which is disposed inside the redistribution substrate 210, through the lower pad 211 of the redistribution substrate 210. The metal bump 260 may include a low melting point metal, such as, tin (Sn) or an alloy including tin (Sn).

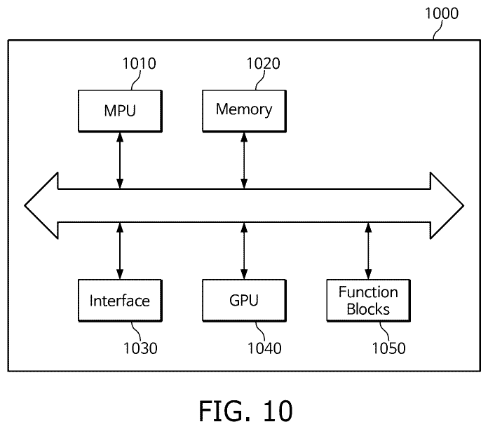

FIG. 10 is a block diagram illustrating a configuration of a semiconductor package according to embodiments of the present inventive concept.

Referring to FIG. 10, the semiconductor package 1000 may include a micro-processing unit 1010, a memory 1020, an interface 1030, a graphics processing unit 1040, functional blocks 1050 and a bus 1060 connecting the same. The semiconductor package 1000 may include both the micro-processing unit 1010 and the graphics processing unit 1040, or may include only one of the two.

The micro-processing unit 1010 may include a core and an L2 cache. For example, the micro-processing unit 1010 may include a multi-core. Each core of the multi-core may have the same or different performances. In addition, each core of the multi-core may be activated at the same time, or activated at different times from each other.

The memory 1020 may store results of processing at the functional blocks 1050 under the control of the micro-processing unit 1010. The interface 1030 may exchange information or signals with external devices. The graphic processing unit 1040 may perform graphic functions. For example, the graphics processing unit 1040 may perform a video codec or process 3D graphics. The functional blocks 1050 may perform various functions. For example, if the semiconductor package 1000 is an application processor (AP) that is used in a mobile device, some of the functional blocks 1050 may perform a communication function. The semiconductor package 1000 may include the semiconductor package 100B described above with reference to FIG. 9.

While the present inventive concept has been described with reference to embodiments thereof, it will be understood by those of ordinary skill in the art that various changes in form and details may be made thereto without departing from the spirit and scope of the present inventive concept.

1. A semiconductor package, comprising:
a package substrate comprising first and second sides that are opposite to each other, and comprising an insulating member and a plurality of redistribution layers respectively disposed at a plurality of different levels of the insulating member and connected to each other;
at least one semiconductor chip disposed on the first side and comprising a plurality of contact pads that are connected to a first redistribution layer of the plurality of redistribution layers that is adjacent to the first side;
a protective layer disposed on the second side and exposing a portion of a second redistribution layer of the plurality of redistribution layers that is adjacent to the second side;
a plurality of under bump metallurgy (UBM) pads disposed on the second side and connected to the exposed portion of the second redistribution layer;
a dummy pattern formed on the protective layer and protruding from the protective layer;
an insulating pattern covering at least a portion of the dummy pattern; and
a passive element disposed on the insulating pattern and a first set of UBM pads of the plurality of UBM pads, and connected to at least some of the first set of UBM pads.

2. The semiconductor package according to claim 1, wherein the plurality of UBM pads are arranged in a grid structure along a row direction and a column direction on the second side.

3. The semiconductor package according to claim 2, wherein the dummy pattern comprises a first dummy pad that is disposed at a center of a unit lattice that comprises four UBM pads of the first set of UBM pads.

4. The semiconductor package according to claim 3, wherein the first dummy pad includes a square or circular shape.

5. The semiconductor package according to claim 2, wherein the dummy pattern comprises a second dummy pad disposed between adjacent UBM pads of the first set of UBM pads.

6. The semiconductor package according to claim 5, wherein the second dummy pad comprises a plurality of second dummy pads that are separated from each other.

7. The semiconductor package according to claim 2, wherein the dummy pattern comprises:
a first dummy pad disposed at a center of a unit lattice that comprises four UBM pads of the first set of UBM pads; and
a second dummy pad disposed between adjacent UBM pads of the first set of UBM pads, and
the first dummy pad and the second dummy pad are integrally formed with each other.

8. The semiconductor package according to claim 1, wherein a protruding thickness of the UBM pad that protrudes from the protective layer is about 80% to about 100% of a thickness of the dummy pattern.

9. The semiconductor package according to claim 1, wherein the dummy pattern is formed of a same material as the plurality of UBM pads.

10. The semiconductor package according to claim 1, wherein the dummy pattern and the plurality of UBM pads are formed to be spaced apart from each other on the second side.

11. The semiconductor package according to claim 10, wherein
a distance between the dummy pattern and the UBM pad, of the plurality of UBM pads, that is adjacent to the dummy pattern is about 10 μm to about 15 μm.

12. The semiconductor package according to claim 10, wherein the insulating pattern is in contact with the UBM pad that is adjacent to the dummy pattern that is covered by the insulating pattern.

13. The semiconductor package according to claim 1, wherein the passive element comprises:
an element body; and
a connection terminal disposed at a corner of the passive element and electrically connecting the passive element to an outside element, and
the at least some UBM pads of the first set of UBM pads are connected to the connection terminal, and
the insulating pattern is in contact with the element body.

14. The semiconductor package according to claim 1, wherein the passive element comprises a land side capacitor (LSC).

15. The semiconductor package according to claim 1, wherein an area of one surface of the passive element is less than a mounting region of the protective layer for the passive element which comprises a region in which the first set of UBM pads are disposed on the second side.

16. The semiconductor package according to claim 1, wherein a connection bump is disposed on a second set of UBM pads of the plurality of UBM pads, which are different from the first set of UBM pads.

17. A semiconductor package, comprising:
a package substrate comprising first and second sides that are opposite to each other, and comprising an insulating member and a plurality of redistribution layers respectively disposed at a plurality of different levels of the insulating member and connected to each other;
at least one semiconductor chip disposed on the first side and comprising a plurality of contact pads that are connected to a first redistribution layer of the plurality of redistribution layers that is adjacent to the first side;
a protective layer disposed on the second side and exposing a portion of a second redistribution layer of the plurality of redistribution layers that is adjacent to the second side;
a plurality of UBM pads disposed on the second side and connected to the exposed portion of the second redistribution layer;
a dummy pattern formed on the protective layer;
an insulating pattern disposed on the dummy pattern; and
a passive element in contact with the insulating pattern, disposed on a first set of UBM pads of the plurality of UBM pads, and connected to at least some of the first set of UBM pads, wherein
the dummy pattern comprises:
a first dummy pad disposed at a center of a unit lattice comprising four UBM pads of the first set of UBM pads; and
a second dummy pad disposed between adjacent UBM pads of the first set of UBM,
the first dummy pad and the second dummy pad are integrally formed with each other, and
the dummy pattern and the plurality of UBM pads are formed to be spaced apart from each other on the second side.

18. A manufacturing method of a semiconductor package, comprising:
manufacturing a package substrate comprising first and second sides that are opposite to each other, and comprising an insulating member and a plurality of redistribution layers respectively disposed at a plurality of different levels of the insulating member and connected to each other;
forming a protective layer on the second side and exposing a portion of a second redistribution layer of the plurality of redistribution layers that is adjacent to the second side;
forming a plurality of UBM pads on the protective layer, wherein the UBM pads are disposed on the second side and adjacent to a dummy pattern, wherein the UBM pads are disposed on the exposed portion of the second redistribution layer;
forming an insulating pattern to cover the dummy pattern; and
placing a passive element on at least some UBM pads of the plurality of UBM pads and to be in contact with the insulating pattern.

19. The manufacturing method according to claim 18, wherein
the plurality of UBM pads and the dummy pattern are formed by a same patterning process, and
the dummy pattern is formed of a same material as the plurality of UBM pads.

20. The semiconductor package according to claim 18, wherein the placing the passive element comprises:
applying solder paste on the at least some UBM pads; and
placing the passive element in contact with the solder paste and the insulating pattern.
